(19) United States
(12) Patent Application Publication
(10) Pub. No.: US 2017/0369703 A1
(43) Pub. Date: Dec. 28, 2017

(54) Thermoplastic Resin Composition and Electronic Device Housing Comprising Same

(71) Applicant: LOTTE ADVANCED MATERIALS CO., LTD., Yeosu-si (KR)

(72) Inventors: Dong In HA, Uiwang-si (KR); Seung Shik SHIN, Uiwang-si (KR); Kyuong Sik CHIN, Uiwang-si (KR)

(21) Appl. No.: 15/543,677

(22) PCT Filed: Apr. 22, 2016
(86) PCT No.: PCT/KR2016/004228

§ 371 Date: Jul. 14, 2017

(30) Foreign Application Priority Data
Apr. 30, 2015 (KR) 10-2015-0062129

(51) Int. Cl. C08L 69/00; H05K 5/02

(52) U.S. Cl. CPC C08L 69/00; H05K 5/0217; C08L 2201/02; C08L 2203/20; C08L 2205/035; C08L 2205/025

(57) ABSTRACT

A thermoplastic resin composition of the present invention includes a polycarbonate resin; a rubber-modified aromatic vinyl graft copolymer; a polyester resin; a glycol-modified polyester resin having about 10 mol % to about 60 mol % of a cyclohexanedimethanol (CHDM) content based on a total amount of a diol component; and a vinyl copolymer including an epoxy group. The thermoplastic resin composition has good impact resistance, flowability, external appearance and the like.

### TECHNICAL FIELD

The present invention relates to a thermoplastic resin composition and an electronic device housing including the same. More specifically, the present invention relates to a thermoplastic resin composition exhibiting good impact resistance, flowability, external appearance, flame resistance and the like, and an electronic device housing including the same.

### BACKGROUND ART

Thermoplastic resin compositions exhibit good physical properties, such as low specific gravity, good moldability, and good impact resistance, as compared with glass or metal, and are useful for housings of electrical/electronic products, automotive interior/exterior materials, and exterior materials for construction. Particularly, with the trend of producing larger and lighter weight electrical/electronic products, plastic products using thermoplastic resins are quickly replacing existing glass or metal-based products.

Among the thermoplastic resin compositions, a polycarbonate/acrylonitrile-butadiene-styrene (PC/ABS) blend obtained by mixing a PC resin with a rubber-modified aromatic vinyl copolymer resin such as ABS may exhibit improved properties in terms of processability, chemical resistance and the like, without deterioration in impact resistance, heat resistance and the like, which may reduce production cost and enable a variety of applications.

In addition, as a multi-component material, adding an easily obtainable material such as a polyester resin to the PC/ABS blend in order to exhibit physical properties which are hardly found in typical thermoplastic resins are researched now.

However, adding a multi-component material to PC or ABS may cause a compatibility problem to deteriorate physical properties of the thermoplastic resin composition, such as impact resistance, flowability, external appearance and the like, and this problem needs to be solved.

One example of the related art is disclosed in Japanese Patent Laid-Open Publication No. 2014-152245.

### DISCLOSURE

### Technical Problem

The present invention provides a thermoplastic resin composition exhibiting good impact resistance, flowability, external appearance, flame resistance and the like.

The present invention provides an electronic device housing produced from the thermoplastic resin composition.

The above and other objects of the present invention may be achieved by the present invention described below.

### Technical Solution

One aspect of the present invention relates to a thermoplastic resin composition. The thermoplastic resin composition may include a polycarbonate resin; a rubber-modified aromatic vinyl graft copolymer; a polyester resin; a glycol-modified polyester resin having about 10 mol % to about 60 mol % of a cyclohexanedimethanol (CHDM) content based on a total amount of a diol component; and a vinyl copolymer including an epoxy group.

In some embodiments, the thermoplastic resin composition may include about 100 parts by weight of the polycarbonate resin; about 1 to about 30 parts by weight of the rubber-modified aromatic vinyl graft copolymer; about 1 to about 30 parts by weight of the polyester resin; about 1 to about 20 parts by weight of the glycol-modified polyester resin; and about 0.5 to about 15 parts by weight of the vinyl copolymer including an epoxy group.

In some embodiments, a weight ratio of the polyester resin to the glycol-modified polyester resin may range from about 1:0.1 to about 1:1.

In some embodiments, the rubber-modified aromatic vinyl graft copolymer may be obtained by graft copolymerization of an aromatic vinyl monomer and a monomer copolymerizable with the aromatic vinyl monomer onto a rubbery polymer.

In some embodiments, the polyester resin may include at least one of polyethylene terephthalate, polybutylene terephthalate, polyethylene naphthalate, polytrimethylene terephthalate, and polycyclohexylene terephthalate.

In some embodiments, the polyester resin may include a recycled polyester resin.

In some embodiments, the glycol-modified polyester resin may have about 30 mol % to about 60 mol % of a cyclohexanedimethanol (CHDM) content based on a total amount of a diol component.

In some embodiments, the vinyl copolymer including an epoxy group may be obtained by copolymerization of (meth)acrylate including an epoxy group, an aromatic vinyl monomer, and a monomer copolymerizable with the aromatic vinyl monomer.

In some embodiments, the vinyl copolymer including an epoxy group may include about 0.01 mol % to about 10 mol % of (meth)acrylate including an epoxy group.

In some embodiments, the thermoplastic resin composition may further include at least one of an inorganic filler, a flame retardant, a flame retardant aid, a release agent, a lubricant, a plasticizer, a heat stabilizer, a dripping inhibitor, an antioxidant, a light stabilizer, a pigment, and a dye.

In some embodiments, the thermoplastic resin composition may have a notched Izod impact strength of about 40 kgf·cm/cm to about 80 kgf·cm/cm as measured on an about ⅛″ thick specimen in accordance with ASTM D256, and a melt flow index (MI) of about 10 g/10 min to about 20 g/10 min as measured at about 260° C. under a load of about 2.16 kg in accordance with ASTM D1238.

Another aspect of the present invention relates to an electronic device housing. The electronic device housing may include a metal frame; and a plastic member facing at least one face of the metal frame, wherein, the plastic member may be produced from the thermoplastic resin composition.

### Advantageous Effects

The present invention provides a thermoplastic resin composition exhibiting good impact resistance, flowability, external appearance, flame resistance and the like, and an electronic device housing including the same.

### DESCRIPTION OF DRAWINGS

FIG. 1 shows a schematic cross-section of an electronic device housing according to one embodiment of the present invention.

FIG. 2 shows a Scanning Electron Microscope (SEM) image of a thermoplastic resin composition specimen prepared in Example 1 of the present invention.

FIG. 3 shows a SEM image of a thermoplastic resin composition specimen prepared in Comparative Example 1 of the present invention.

FIG. 4 shows a SEM image of a thermoplastic resin composition specimen prepared in Comparative Example 2 of the present invention.

FIG. 5 shows a SEM image of a thermoplastic resin composition specimen prepared in Comparative Example 3 of the present invention.

### BEST MODE

Hereinafter, embodiments of the present invention will be described in detail.

A thermoplastic resin composition according to the present invention may include (A) a polycarbonate resin; (B) a rubber-modified aromatic vinyl graft copolymer; (C) a polyester resin; (D) a glycol-modified polyester resin having about 10 mol % to about 60 mol % of a cyclohexanedimethanol (CHDM) content based on a total amount of a diol component; and a vinyl copolymer including an epoxy group.

(A) Polycarbonate Resin

The polycarbonate resin used in the present invention may include any typical polycarbonate resin known in the art of thermoplastic resin composition. For example, the polycarbonate resin may include an aromatic polycarbonate resin prepared by reacting a precursor such as phosgene, halogen formate, and carbonate diester with diphenols (aromatic diol compounds).

Examples of the diphenols may include 4,4′-biphenol, 2,2-bis(4-hydroxyphenyl)propane, 2,4-bis(4-hydroxyphenyl)-2-methylbutane, 1,1-bis(4-hydroxyphenyl)cyclohexane, 2,2-bis(3-chloro-4-hydroxyphenyl)propane, 2,2-bis(3,5-dichloro-4-hydroxyphenyl)propane and the like, without being limited thereto. For example, 2,2-bis(4-hydroxyphenyl)propane, 2,2-bis(3,5-dichloro-4-hydroxyphenyl)propane, and 1,1-bis(4-hydroxyphenyl)cyclohexane may be used. Specifically, 2,2-bis(4-hydroxyphenyl)propane, which is also referred to as bisphenol-A, may be used.

The polycarbonate resin may include a branched polycarbonate resin, and may be prepared by adding about 0.05 mol % to about 2 mol % of a polyfunctional compound containing tri- or higher functional groups, for example, tri- or higher-valent phenol groups, based on the total amount of the diphenols used in polymerization.

The polycarbonate resin may be used in the form of a homo-polycarbonate resin, a co-polycarbonate resin, or a blend thereof.

In addition, the polycarbonate resin may be partially or completely replaced by an aromatic polyester-carbonate resin obtained by a polymerization reaction in the presence of an ester precursor, for example, a bifunctional carboxylic acid.

In exemplary embodiments, the polycarbonate resin may have a weight average molecular weight (Mw) of about 10,000 g/mol to about 200,000 g/mol, for example about 15,000 g/mol to about 40,000 g/mol, as measured by gel permeation chromatography (GPC), without being limited thereto.

In exemplary embodiments, the polycarbonate resin may have a melt flow index (MI) of about 5 g/10 min to about 40 g/10 min, as measured at about 250° C. under a load of about 10 kg in accordance with ISO 1133, without being limited thereto. In exemplary embodiments, the polycarbonate resin may include a mixture of at least two polycarbonate resins having different melt indices.

(B) Rubber-Modified Aromatic Vinyl Graft Copolymer

The rubber-modified aromatic vinyl graft copolymer used in the present invention may include a copolymer obtained by graft copolymerization of an aromatic vinyl monomer and a monomer copolymerizable with the aromatic vinyl monomer onto a rubbery polymer.

In exemplary embodiments, the rubber-modified aromatic vinyl graft copolymer may be obtained by adding an aromatic vinyl monomer, a monomer copolymerizable with the aromatic vinyl monomer and the like, to a rubbery polymer, with further inclusion of a monomer for imparting processability and heat resistance if necessary, followed by polymerization (graft copolymerization) thereof. The polymerization process may be performed by any polymerization method known in the art, such as emulsion polymerization, suspension polymerization, bulk polymerization and the like.

In exemplary embodiments, the rubbery polymer may include diene rubbers such as polybutadiene, poly(styrene-butadiene), poly(acrylonitrile-butadiene) and the like; saturated rubbers obtained by adding hydrogen to the diene rubbers; isoprene rubbers; acrylic rubbers such as poly(butyl acrylate); and ethylene-propylene-diene monomer terpolymers (EPDM), without being limited thereto. These can be used alone or in combinations thereof. For example, the rubbery polymer may include a diene rubber, specifically a butadiene based rubber. The rubbery polymer may be present in an amount of about 5 wt % to about 65 wt %, for example about 10 wt % to about 60 wt %, specifically about 20 wt % to about 50 wt %, based on the total weight (100 wt %) of the rubber-modified aromatic vinyl graft copolymer. Within this range, the thermoplastic resin composition may exhibit good impact resistance, mechanical properties and the like. The rubbery polymer (rubber particles) may have an average (Z-average) particle size of about 0.05 μm to about 6 μm, for example about 0.15 μm to about 4 μm, specifically about 0.25 μm to about 3.5 μm. Within this range, the thermoplastic resin composition may exhibit good impact resistance, external appearance, flame resistance and the like.

In exemplary embodiments, the aromatic vinyl monomer may include any aromatic vinyl monomer which is graft-copolymerizable with the rubbery copolymer. Examples of the aromatic vinyl monomer may include styrene, α-methylstyrene, β-methylstyrene, p-methylstyrene, p-t-butylstyrene, ethylstyrene, vinylxylene, monochlorostyrene, dichlorostyrene, dibromostyrene, vinylnaphthalene and the like, without being limited thereto. These can be used alone or in combinations thereof. The aromatic vinyl monomer may be present in an amount of about 15 wt % to about 94 wt %, for example about 20 wt % to about 80 wt %, specifically about 30 wt % to about 60 wt %, based on the total weight (100 wt %) of the rubber-modified aromatic vinyl graft copolymer. Within this range, the thermoplastic resin composition may exhibit good impact resistance, mechanical properties and the like.

In exemplary embodiments, the monomer copolymerizable with the aromatic vinyl monomer may include vinyl cyanide compounds such as acrylonitrile, methacrylonitrile, ethacrylonitrile, phenylacrylonitrile, α-cloroacrylonitrile, pumaronitirle and the like. These monomers can be used alone or in combinations thereof. The monomer copolymerizable with the aromatic vinyl monomer may be present in an amount of about 1 wt % to about 50 wt %, for example about 5 wt % to about 45 wt %, specifically about 10 wt % to about 30 wt %, based on the total weight of the rubber-modified aromatic vinyl graft copolymer. Within this range, the thermoplastic resin composition may exhibit good impact resistance, mechanical properties and the like.

In exemplary embodiments, the monomer for imparting processability and heat resistance may include acrylic acid, methacrylic acid, maleic anhydride, N-substituted maleimide and the like, without being limited thereto. These can be used alone or in combinations thereof. The monomer for imparting processability and heat resistance may be present in an amount of about 15 wt % or less, for example about 0.1 wt % to about 10 wt %, based on the total weight of the rubber-modified aromatic vinyl graft copolymer. Within this range, processability, mechanical properties, flame resistance and the like of the thermoplastic resin composition may improve without deterioration in other properties.

In exemplary embodiments, the rubber-modified aromatic vinyl graft copolymer may be present in an amount of about 1 to about 30 parts by weight, for example about 5 to about 25 parts by weight, specifically about 10 to about 25 parts by weight, based on 100 parts by weight of the polycarbonate resin. Within this range, the thermoplastic resin composition may exhibit good impact resistance, mechanical properties and the like.

(C) Polyester Resin

The polyester resin may resin used in the present invention may include any typical polyester resin known in the art of the thermoplastic resin composition, except for the glycol-modified polyester resin. For example, the polyester resin may be prepared by condensation polymerization of a dicarboxylic acid component and a diol component. Examples of the dicarboxylic acid component may include, without limitation, aromatic dicarboxylic acid such as terephthalic acid (TPA), isophthalic acid (IPA), 1,2-naphthalene dicarboxylic acid, 1,4-naphthalene dicarboxylic acid, 1,5-naphthalene dicarboxylic acid, 1,6-naphthalene dicarboxylic acid, 1,7-naphthalene dicarboxylic acid, 1,8-naphthalene dicarboxylic acid, 2,3-naphthalene dicarboxylic acid, 2,6-naphthalene dicarboxylic acid, 2,7-naphthalene dicarboxylic acid and the like; aromatic dicarboxylate such as dimethyl terephthalate (DMT), dimethyl isophthalate, dimethyl-1,2-naphthalate, dimethyl-1,5-naphthalate, dimethyl-1,7-naphthalate, dimethyl-1,7-naphthalate, dimethyl-1,8-naphthalate, dimethyl-2,3-naphthalate, dimethyl-2,6-naphthalate, dimethyl-2,7-naphthalate and the like. Examples of the diol component may include, without limitation, ethylene glycol, 1,2-propylene glycol, 1,3-propylene glycol, 2,2-dimethyl-1,3-propane diol, 1,3-butanediol, 1,4-butanediol, 1,5-pentanediol, 1,6-hexanediol and the like.

In exemplary embodiments, the polyester resin may include at least one of polyethylene terephthalate (PET), polybutylene terephthalate (PBT), polyethylene naphthalate (PEN), and polytrimethylene terephthalate (PTT).

In exemplary embodiments, the polyester resin may include a recycled polyester resin. For example, the recycled polyester resin may include a recycled polyethylene terephthalate (PET). This kind of recycled polyester resin may be directly crushed from a bottle, a sheet and the like which are made from a polyester resin, or the recycled polyester resin may re-extruded therefrom. The recycled polyester resin may be used in a form of a pellet, without being limited thereto. Use of the recycled polyester resin may be good for its eco-friendly effect.

In exemplary embodiments, the polyester resin may have an inherent viscosity of about 0.4 dl/g to about 1.5 dl/g, for example about 0.5 dl/g to about 1.2 dl/g, as measured at 35° C. using an o-chlorophenol solution (concentration: about 0.5 g/dl). Within this range, the thermoplastic resin composition may exhibit good heat resistance, mechanical strength, flowability and the like.

In exemplary embodiments, the polyester resin may be present in an amount of about 1 to about 30 parts by weight, for example about 5 to about 25 parts by weight, specifically about 10 to about 20 parts by weight, based on about 100 parts by weight of the polycarbonate resin. Within this range, the thermoplastic resin composition may exhibit good heat resistance, mechanical strength, flowability and the like.

(D) Glycol-Modified Polyester Resin

The glycol-modified polyester resin used in the present invention may include a polyester resin having about 10 mol % to about 60 mol % of a 1,4-cyclohexanedimethanol (CHDM) content based on a total amount of a diol component. The glycol-modified polyester resin may improve miscibility of the components of the thermoplastic resin composition to enable the polyester resin, the rubber-modified aromatic vinyl graft copolymer and the like are uniformly dispersed in a matrix (polycarbonate resin) in small sizes. The glycol-modified polyester resin may also inhibit increase of the degree of crystallization of the polyester resin to reduce post-deformation and post-shrinkage of a product molded from the thermoplastic resin composition.

In exemplary embodiments, the glycol-modified polyester resin may be prepared by condensation polymerization of a dicarboxylic acid component and a diol component. Examples of the dicarboxylic acid component may include terephthalic acid, and examples of the diol component may include a mixture including about 40 mol % to about 90 mol %, for example about 40 mol % to about 70 mol % of C₂-C₆ alkylene glycol and about 10 mol % to about 60 mol %, for example about 30 mol % to about 60 mol % of 1,4-cyclohexanedimethanol (CHDM). Within this range, the aforementioned effects may be obtained.

In exemplary embodiments, the glycol-modified polyester resin may have an inherent viscosity of about 0.5 dl/g to about 0.7 dl/g, for example about 0.55 dl/g to about 0.65 dl/g, as measured at 35° C. using an o-chlorophenol solution (concentration: about 0.5 g/dl). Within this range, miscibility of the components of the thermoplastic resin composition may improve, and the thermoplastic resin composition may exhibit good impact resistance, flowability, dimensional stability, external appearance and the like.

In exemplary embodiments, the glycol-modified polyester resin may be present in an amount of about 1 to about 20 parts by weight, for example about 2 to about 18 parts by weight, specifically about 5 to 15 parts by weight, based on 100 parts by weight of the polycarbonate resin. Within this range, miscibility of the components of the thermoplastic resin composition may improve, and the thermoplastic resin composition may exhibit good impact resistance, flowability, dimensional stability, external appearance and the like.

A weight ratio of the polyester resin to the glycol-modified polyester resin may range from about 1:0.1 to about 1:1, for example about 1:0.3 to about 1:0.7. Within this range, miscibility of the components of the thermoplastic resin composition may further improve.

(E) Vinyl Copolymer Including an Epoxy Group

The vinyl copolymer including an epoxy group used in the present invention may improve miscibility of the components of the thermoplastic resin composition, together with the glycol-modified polyester resin. The vinyl copolymer including an epoxy group may enable a uniform dispersion of the polyester resin, the rubber-modified aromatic vinyl graft copolymer and the like in a matrix (polycarbonate resin) to greatly improve physical properties of each component of the thermoplastic resin composition.

In exemplary embodiments, the vinyl copolymer including an epoxy group may be prepared by copolymerization of (meth)acrylate including an epoxy group, an aromatic vinyl monomer, and a monomer copolymerizable with the aromatic vinyl monomer.

In exemplary embodiments, the vinyl copolymer including an epoxy group may be obtained by mixing (meth)acrylate including an epoxy group, an aromatic vinyl monomer, and a monomer copolymerizable with the aromatic vinyl monomer, followed by polymerization thereof. The polymerization process may be performed by any polymerization method known in the art, such as emulsion polymerization, suspension polymerization, bulk polymerization and the like.

In exemplary embodiments, examples of the (meth)acrylate including an epoxy group may include glycidyl methacrylate, glycidyl acrylate and the like, without being limited thereto. These can be used alone or in combinations thereof. The (meth)acrylate including an epoxy group may be present in an amount of about 0.01 wt % to about 10 wt %, for example about 0.05 wt % to about 5 wt %, specifically about 0.1 mol % to about 1 mol %, based on the total weight (100 wt %) of the vinyl copolymer including an epoxy group. Within this range, miscibility of each component of the thermoplastic resin composition may improve.

In exemplary embodiments, the aromatic vinyl monomer may include styrene, α-methylstyrene, β-methylstyrene, p-methylstyrene, p-t-butylstyrene, ethylstyrene, vinylxylene, monochlorostyrene, dichlorostyrene, dibromostyrene, vinylnaphthalene and the like, without being limited thereto. These can be used alone or in combinations thereof. The aromatic vinyl monomer may be present in an amount of about 20 wt % to about 90 wt %, for example about 30 wt % to about 60 wt %, based on the total weight (100 wt %) of the vinyl copolymer including an epoxy group. Within this range, miscibility of each component of the thermoplastic resin composition may improve.

In exemplary embodiments, the monomer copolymerizable with the aromatic vinyl monomer may include vinyl cyanide compounds, such as acrylonitrile, methacrylonitrile, ethacrylonitrile, phenylacrylonitrile, α-cloroacrylonitrile, pumaronitirle and the like. These can be used alone or in combinations thereof. The monomer copolymerizable with the aromatic vinyl monomer may be present in an amount of about 5 wt % to about 70 wt %, for example about 10 to about 50 wt %, based on the total weight (100 wt %) of the vinyl copolymer including an epoxy group. Within this range, miscibility of each component of the thermoplastic resin composition may improve.

In exemplary embodiments, the vinyl copolymer including an epoxy group may be present in an amount of about 0.5 to about 15 parts by weight, for example about 1 to about 13 parts by weight, specifically about 1 to about 10 parts by weight, based on about 100 parts by weight of the polycarbonate resin. Within this range, miscibility of the components of the thermoplastic resin composition may improve, and the thermoplastic resin composition may have good impact resistance, flowability, dimensional stability, external appearance and the like.

In exemplary embodiments, a weight ratio of the glycol-modified polyester resin to the vinyl copolymer including an epoxy resin may range from about 1:1 to about 15:1, without being limited thereto.

In addition, the thermoplastic resin composition according to embodiments of the present invention may further include an additive such as an inorganic filler, a flame retardant, a flame retardant aid, a release agent, a lubricant, a plasticizer, a heat stabilizer, a dripping inhibitor, an antioxidant, a light stabilizer, a pigment, a dye, and mixtures thereof.

In exemplary embodiments, any additive known in the art of the thermoplastic resin composition may be used without limitation. Examples of the inorganic filler may include glass fibers, wollastonite, whiskers, basalt fibers, talc, mica, without being limited thereto. For example, the inorganic filler may be present in an amount of about 0.1 to about 10 parts by weight, for example about 0.5 to about 5 parts by weight, based on about 100 parts by weight of the polycarbonate resin. Within this range, the polycarbonate resin composition may exhibit good external appearance, mechanical properties, dimensional stability, flame resistance and the like.

Examples of an additive except for the inorganic filler may include a flame retardant such as red phosphorus, phosphate compounds, phosphonate compounds, phosphinate compounds, phosphine oxide compounds, phosphazene compounds and metal salts thereof; a release agent such as polyethylene wax, fluorine-containing polymer, silicon oil, metal salts of stearic acid, metal salts of montanic acid, montanic ester wax and the like; a nucleating agent such as clay and the like; an antioxidant such as hindered phenol compounds and the like; and mixtures thereof, without being limited thereto. The additive except for the inorganic filler may be present in an amount of about 0.1 to about 40 parts by weight based on about 100 parts by weight of the polycarbonate resin, without being limited thereto.

The thermoplastic resin composition according to embodiments of the present invention may be prepared in a pellet form by mixing the above described components, followed by melt extrusion of the mixture at about 200° C. to about 280° C., for example about 250° C. to about 260° C., through a typical twin-screw extruder.

In exemplary embodiments, the thermoplastic resin composition may have a notched Izod impact strength of about 40 kgf·cm/cm to about 80 kgf·cm/cm, for example about 45 kgf·cm/cm to about 60 kgf·cm/cm, as measured on an about ⅛″ thick specimen in accordance with ASTM D256. The thermoplastic resin composition may have a melt flow index (MI) of about 10 g/10 min to about 25 g/10 min, for example about 12 g/10 min to about 19 g/10 min, as measured at about 260° C. under a load of about 2.16 kg in accordance with ASTM D1238.

FIG. 1 shows a schematic cross-section of an electronic device housing according to one embodiment of the present invention. In the drawings, the dimensions of components may be exaggerated for clarity of illustration, and the drawings are provided for illustration only and are not to be construed in any way as limiting the present invention. As shown in FIG. 1, the electronic device housing according to one embodiment of the present invention may have a metal frame 10; and a plastic member 20 facing at least one face of the metal frame 10. The plastic member 20 may be produced from the above described thermoplastic resin composition.

In exemplary embodiments, the metal frame 10 and the plastic member 20 may have a variety of shapes without being limited to the drawing. However, at least one face of the metal frame 10 may face at least one face of the plastic member 20. The faced structure may be embodied by adhesion, insertion and the like, without being limited thereto.

In exemplary embodiments, the metal frame 10 may include a stainless-steel frame and the like typically used in electronic device housings including the plastic member. The metal frame 10 may be easily obtainable in commercial markets.

In exemplary embodiments, the plastic member 20 may be produced from the polycarbonate resin composition through a variety of molding methods such as injection molding, extrusion molding, vacuum molding, casting molding and the like. For example, the plastic member 20 may be used in a front cover, a rear cover and the like of a television, a monitor and the like having a size of about 22 inches to about 70 inches.

In exemplary embodiments, a coefficient of thermal expansion (CTE) difference between the metal frame and the plastic member may range from about 0.1 to about 0.5, for example about 0.3 to about 0.45.

### MODE FOR INVENTION

Hereinafter, the present invention will be described in more detail with reference to some examples. It should be understood that these examples are provided for illustration only and are not to be construed in any way as limiting the present invention. Descriptions of details apparent to those skilled in the art will be omitted for clarity.

### EXAMPLE

Details of components used in the following Examples and Comparative Examples are as follows.

(A) Polycarbonate resin

(A1) Bisphenol-A based polycarbonate resin (Melt flow index as measured at 250° C. under a load of 10 kg in accordance with ISO 1133: 10.5±0.5 g/10 min) was used.

(A2) Bisphenol-A based polycarbonate resin (Melt flow index as measured at 250° C. under a load of 10 kg in accordance with ISO 1133: 30.0±0.5 g/10 min) was used.

(B) Rubber-modified aromatic vinyl graft copolymer

g-ABS obtained by graft copolymerization of 55 wt % of a mixture of styrene and acrylonitrile (weight ratio 73:27) to 45 wt % of polybutadiene rubber (PBR) having Z-average of 310 nm was used.

(C) Polyester Resin

Recycled polyethylene terephthalate (Polycom, Inc., Product name: PETR 10, intrinsic viscosity: 0.6 to 0.8 dl/g) was used.

(D) Glycol-modified polyester resin

Glycol-modified polyethylene terephthalate (PMT International Co., Ltd., Product name: PTGR10/20) having 45 mol % of a cyclohexanedimethanol (CHDM) content based on a total amount of a diol component was used.

(E) Vinyl copolymer including an epoxy group

Glycidylmethacrylate-styrene-acrylonitrile copolymer (GMA-SAN, prepared from polymerization of 1 mol % of glycidylmethacrylate and 99 mol % of a mixture of styrene and acrylonitrile (mole ratio 85:15)) was used.

### Examples 1 to 3 and Comparative Examples 1 to 3

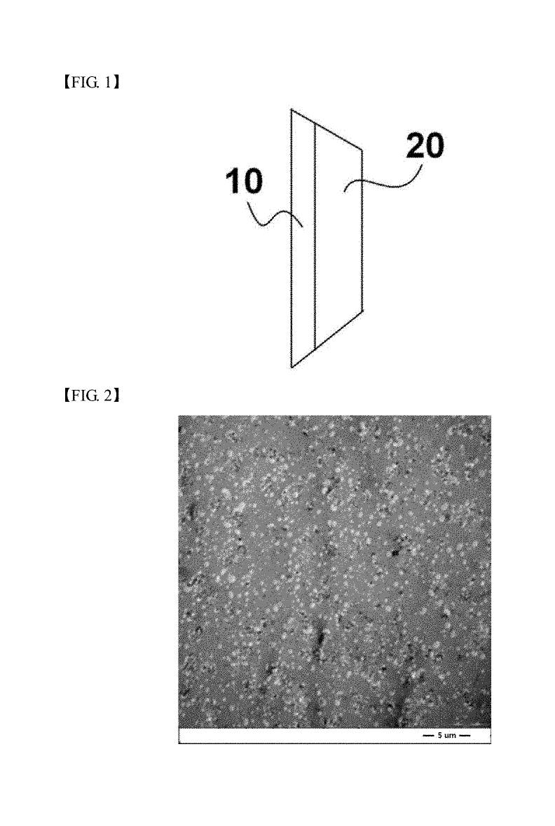

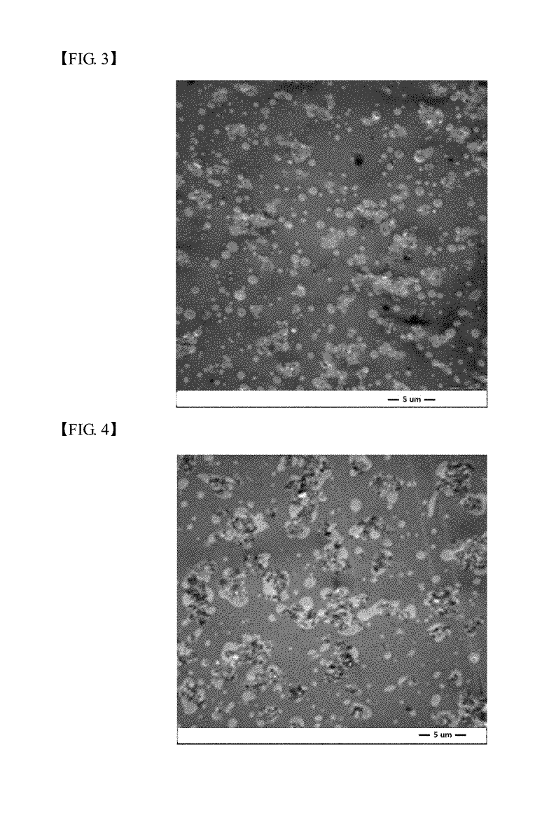

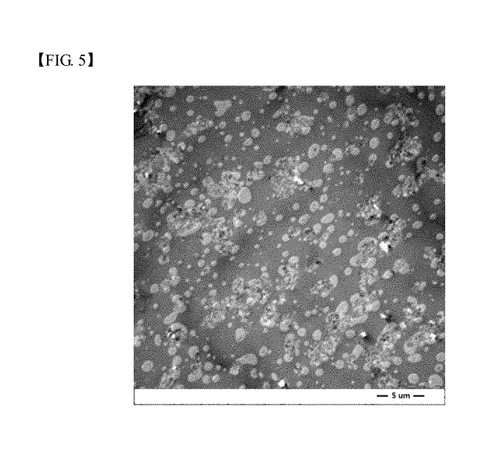

The aforementioned components were added in amounts as listed in Table 1, followed by extrusion at 250° C. to prepare pellets. Extrusion was performed using a twin-screw extruder (L/D=36, diameter 45 mm) and the prepared pellets were dried at 80° C. to 100° C. for 4 hours or more and subjected to injection molding in a 6 Oz molding machine (molding temperature: 280° C., mold temperature: 60° C.) to prepare specimens. The prepared specimens were evaluated as to the following properties and the results are shown in Table 1. Scanning Electron Microscope (SEM) images of the specimens of the thermoplastic resin compositions prepared in Example 1 and Comparative Examples 1, 2 and 3 are shown in FIGS. 2, 3, 4 and 5, respectively.

Property Evaluation

(1) Notched Izod impact strength (unit: kgf·cm/cm): Notched Izod impact strength was measured on a ⅛″ thick notched Izod specimen in accordance with ASTM D256.

(2) Melt flow index (MI, unit: g/10 min): Melt flow index was measured at 260° C. under a load of 2.16 kg in accordance with ASTM D1238.

TABLE 1

| | | Example | | | Comparative Example | | |
|---|---|---|---|---|---|---|---|
| | | 1 | 2 | 3 | 1 | 2 | 3 |
| (A) | (A1) (wt %) | 32.8 | 32.8 | 32.8 | 32.8 | 32.8 | 32.8 |
| | (A2) (wt %) | 67.2 | 67.2 | 67.2 | 67.2 | 67.2 | 67.2 |

| | | | | | | |
|---|---|---|---|---|---|---|
| (B) (parts by weight) | 21.9 | 21.9 | 21.9 | 21.9 | 21.9 | 21.9 |
| (C) (parts by weight) | 20.3 | 20.3 | 20.3 | 20.3 | 20.3 | 20.3 |
| (D) (parts by weight) | 10.9 | 10.9 | 10.9 | 10.9 | — | — |
| (E) (parts by weight) | 1.6 | 4.7 | 7.8 | — | 4.7 | — |
| Notched Izod impact | 55 | 50 | 46 | 56 | 15 | 16 |
| strength (kgf · cm/cm) | | | | | | |
| Melt flow index (g/10 | 13.8 | 14.2 | 16.0 | 13.3 | 15.2 | 14.5 |
| min) | | | | | | |

* Parts by weight: parts by weight based on 100 parts by weight of (A) polycarbonate resin

From Table 1 and FIGS. 2, 3, 4 and 5, it can be seen that in each of the thermoplastic resin compositions according to the present invention, components such as the polyester resin, the rubber-modified aromatic vinyl graft copolymer and the like are uniformly dispersed in the polycarbonate resin matrix, and the thermoplastic resin compositions according to the present invention all have good impact resistance, flowability, external appearance, flame resistance and the like.

Conversely, the thermoplastic resin compositions of Comparative Examples 1 to 3 have large domains and low dispersities compared to the thermoplastic resin compositions of Examples 1 to 3. In addition, flowability (as in Comparative Example 1) or impact resistance (as in Comparative Examples 2 and 3) of each thermoplastic composition is deteriorated.

It should be understood that various modifications, changes, alterations, and equivalent embodiments can be made by those skilled in the art without departing from the spirit and scope of the present invention.

1. A thermoplastic resin composition comprising:
a polycarbonate resin;
a rubber-modified aromatic vinyl graft copolymer;
a polyester resin;
a glycol-modified polyester resin having about 10 mol % to about 60 mol % of a cyclohexanedimethanol (CHDM) content based on a total amount of a diol component; and
a vinyl copolymer comprising an epoxy group.

2. The thermoplastic resin composition according to claim 1, wherein the thermoplastic resin composition comprises: about 100 parts by weight of the polycarbonate resin; about 1 to about 30 parts by weight of the rubber-modified aromatic vinyl graft copolymer; about 1 to about 30 parts by weight of the polyester resin; about 1 to about 20 parts by weight of the glycol-modified polyester resin; and about 0.5 to about 15 parts by weight of the vinyl copolymer comprising an epoxy group.

3. The thermoplastic resin composition according to claim 1, wherein a weight ratio of the polyester resin to the glycol-modified polyester resin ranges from about 1:0.1 to about 1:1.

4. The thermoplastic resin composition according to claim 1, wherein the rubber-modified aromatic vinyl graft copolymer is obtained by graft copolymerization of an aromatic vinyl monomer and a monomer copolymerizable with the aromatic vinyl monomer onto a rubbery polymer.

5. The thermoplastic resin composition according to claim 1, wherein the polyester resin comprises at least one of polyethylene terephthalate, polybutylene terephthalate, polyethylene naphthalate, polytrimethylene terephthalate, and polycyclohexylene terephthalate.

6. The thermoplastic resin composition according to claim 1, wherein the polyester resin comprises a recycled polyester resin.

7. The thermoplastic resin composition according to claim 1, wherein the glycol-modified polyester resin has about 30 mol % to about 60 mol % of a cyclohexanedimethanol (CHDM) content based on a total amount of a diol component.

8. The thermoplastic resin composition according to claim 1, wherein the vinyl copolymer comprising an epoxy group is obtained by copolymerization of (meth)acrylate comprising an epoxy group, an aromatic vinyl monomer, and a monomer copolymerizable with the aromatic vinyl monomer.

9. The thermoplastic resin composition according to claim 1, wherein the vinyl copolymer comprising an epoxy group comprises about 0.01 mol % to about 10 mol % of (meth)acrylate comprising an epoxy group.

10. The thermoplastic resin composition according to claim 1, further comprising at least one of an inorganic filler, a flame retardant, a flame retardant aid, a release agent, a lubricant, a plasticizer, a heat stabilizer, a dripping inhibitor, an antioxidant, a light stabilizer, a pigment, and a dye.

11. The thermoplastic resin composition according to claim 1, wherein the thermoplastic resin composition has a notched Izod impact strength of about 40 kgf·cm/cm to about 80 kgf·cm/cm as measured on an about ⅛″ thick specimen in accordance with ASTM D256, and a melt flow index (MI) of about 10 g/10 min to about 25 g/10 min as measured at about 260° C. under a load of about 2.16 kg in accordance with ASTM D1238.

12. An electronic device housing comprising:
a metal frame; and
a plastic member facing at least one face of the metal frame,
wherein the plastic member is produced from the thermoplastic resin composition according to claim 1.
